(19) United States
(12) Patent Application Publication
(10) Pub. No.: US 2006/0221561 A1
(43) Pub. Date: Oct. 5, 2006

(54) COVER MECHANISM FOR DATA STORAGE DEVICE

(76) Inventors: Qin Guo, Shenzhen (CN); Guang-Yao Lee, Shenzhen (CN)

Correspondence Address: NORTH AMERICA INTELLECTUAL PROPERTY CORPORATION, P.O. BOX 506, MERRIFIELD, VA, 22116, US

(21) Appl. No.: 11/307,047

(22) Filed: Jan. 20, 2006

(30) Foreign Application Priority Data
Apr. 3, 2005 (CN) 200520056693.2

(51) Int. Cl. H05K 7/00

(52) U.S. Cl. 361/679

(57) ABSTRACT

A cover mechanism for protecting a storage device from contamination and included a bezel (3), a cover (1), a resilient member (2), and a pair of relay members (4). The bezel defines an opening (31) for the storage device passing therethrough, a pair of slots (32) for receiving the relay members therein, and a pair of first holes (342) defined in sidewall thereof. The cover includes a pair of tabs (15) each defining a second hole (151) therein. Each of the relay members includes a first shaft (45) extending from a resilient tab (43) at one end thereof, and a second shaft (47) at the other end thereof. The first shafts pivotally engage the first holes of the bezel. The second shafts pivotally engage in the second holes of the cover. Two ends of the resilient member are separately fixed to the cover and the bezel.

### CROSS-REFERENCES TO RELATED APPLICATION

Related subject matter is disclosed in a co-pending U.S. patent application with same title and assigned to the same assignee with this application.

### FIELD OF THE INVENTION

The present invention relates to cover mechanisms, and particularly to a cover mechanism which can protect a data storage device from contamination and humidity.

### DESCRIPTION OF RELATED ART

Data storage devices, such as optical disk drives, are installed in a computer enclosure for communication and processing data. An optical disk drive includes a case and a tray received in the case. The tray can accommodate an optical disk therein. A front bezel is positioned in front of the computer enclosure. An opening is defined in the front bezel. The tray can be moved into or out of the enclosure through the opening of the front bezel.

For example, a typical personal computer includes an enclosure for protection of internal devices, such as hard disk drives, compact disk read-only memory (CD-ROM) drives, a motherboard, and the like. To access the CD-ROM drive, an opening is defined in the enclosure. However, contamination and humidity often harm the personal computer via the opening.

To address aforementioned problem, an enclosure having a protective cover as described in China Patent No. 98220678.X is invented. The enclosure includes a front panel defining an opening, and a cover is pivotably attached to the front panel via pivots for shielding the opening. However, the cover includes a protruding part which always extends out of a front bezel no matter the cover is open or closed so that the cover is prone to be damaged in transportation or in use due to any accidental impact. This contingency usually leads to a short life and an unpleasant appearance of the cover.

What is desired, therefore, is a cover mechanism protecting a data storage device from any accidental damage.

### SUMMARY OF INVENTION

In one preferred embodiment, a cover mechanism for protecting a storage device from contamination and included a bezel, a cover, a resilient member, and a pair of relay members. The bezel defines an opening for the storage device passing therethrough, a pair of slots for receiving the relay members therein, and a pair of first holes defined in sidewalls thereof. The cover includes a pair of tabs each defining a second hole therein. Each of the relay members includes a first shaft extending from a resilient tab at one end thereof, and a second shaft at the other end thereof. The first shafts pivotally engage in the first holes of the bezel. The second shafts pivotally engage in the second holes of the cover. Two ends of the resilient member are separately attached to the cover and the bezel.

Other advantages and novel features will become more apparent from the following detailed description of preferred embodiments when taken in conjunction with the accompanying drawings, in which:

### BRIEF DESCRIPTION OF DRAWINGS

FIGS. 1 and 2 are exploded, isometric views of a cover mechanism in accordance with a preferred embodiment of the present invention, but viewed from different aspects;

FIGS. 3 and 5 are assembled views of FIG. 2, but viewed from different aspects and respectively schematically showing the cover mechanism in different working states; and

FIG. 4 is a cross sectional view of FIG. 3.

### DETAILED DESCRIPTION

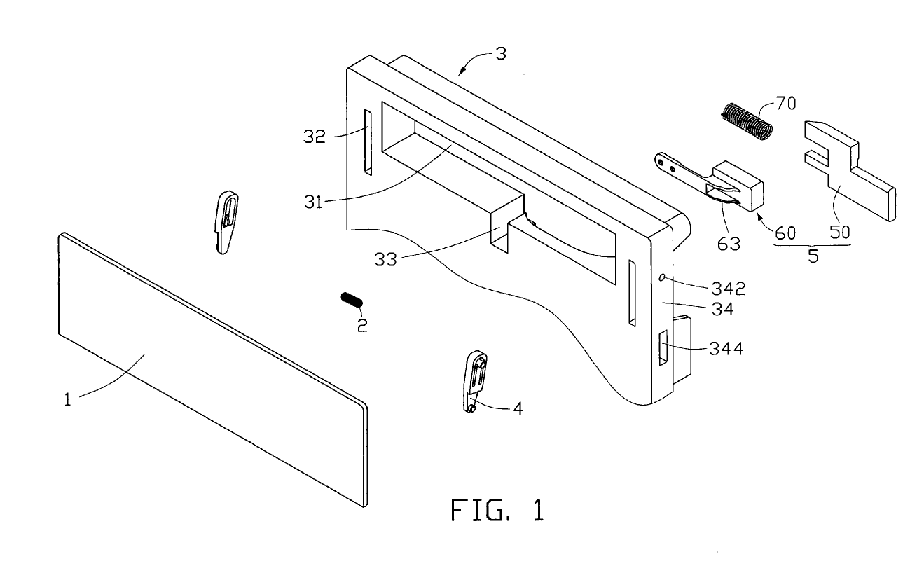

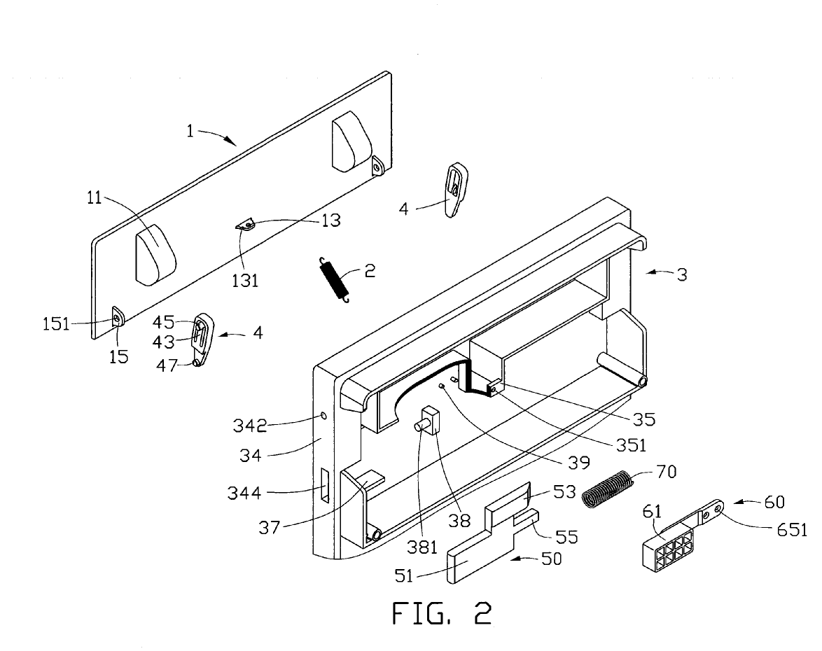

Referring to FIGS. 1 and 2, a cover mechanism of an electronic appliance in accordance with the preferred embodiment of the present invention is provided for protecting storage devices from accidental damage. The cover mechanism includes a bezel 3, a cover 1 attached to the bezel 3, a resilient member 2 disposed between the cover 1 and the bezel 3, and a pair of relay members 4 movably connecting the cover 1 to the bezel 3. A button assembly 5 is attached to the bezel 3 to actuate the storage devices.

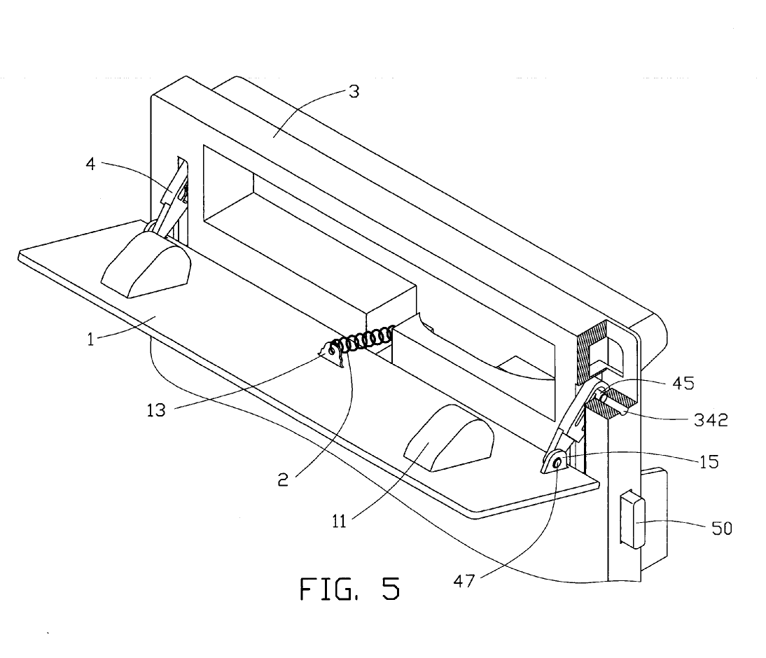

Referring also to FIG. 5, the bezel 3 includes an opening 31, and a pair of slots 32 defined therein. The opening 31 is provided an entrance for a storage device (not shown) moving therethrough. A recess 33 is defined in the bezel 3 and connects to a lower portion of the opening 31. The slots 32 are defined in the bezel 3 besides the opening 31. A pair of first holes 342 is defined in sidewalls 34 of the bezel 3 and connects to the slots 32. A channel 344 is defined a left sidewall 34 below the corresponding first hole 342. A first fixing board 35 is formed at an inner edge of the recess 33. A first fixing aperture 351 is defined in the first fixing board 35. A guiding tab 37 and a block 38 extend perpendicularly from an inner surface of the bezel 3, corresponding the channel 344. The block 38 includes a post 381 extending perpendicularly therefrom, toward the channel 344. A pair of fixing pins 39 extrudes from the inner surface of the bezel 3, besides the block 38.

The cover 1 includes a pair of triangular protrusions 11 extending from an inner side thereof. A second fixing board 13 perpendicularly extends from the cover 1 between the protrusions 11. A second fixing aperture 131 is defined in the second fixing board 13. A pair of tabs 15 vertically extends from the cover 1 below the protrusions 11. A pivoting hole 151 is defined in each of the tabs 15.

Each of the relay members 4 includes a resilient tab 43 extending from a middle portion thereof, a first shaft 45, and a second shaft 47. Each of the first shafts 45 extends perpendicularly from a free end of the corresponding resilient tab 43, near one end of the corresponding relay member 4. Each of the second shafts 47 extends perpendicularly from an opposite end of the corresponding relay members 4. Each of the shafts 41 is formed at one end of the corresponding relay member 4 and pivotally received in the corresponding pivoting hole 151 of the cover 1. The first shafts 45 pivotally engage in the first holes 342 of the bezel 3. The second shafts 47 pivotally engage in the second holes 151 of the tabs 15 of the cover 1.

The resilient member 2 is contained in the recess 33 of the bezel 3 when the cover 1 covers the bezel 3. In the preferred embodiment of the present invention, the resilient member 2 is a coil spring, with its two ends separately fixed in the first fixing aperture 351 of the bezel 3 and the second fixing aperture 131 of the cover 1.

The button assembly 5 includes a button 50, a trigger member 60, and a spring 70. The trigger member 60 includes a sloping portion 63, a touch portion 61, and a pair of through holes 651 defined in one end thereof. The button 50 includes a wedge portion 53 engaging with the sloping portion 63 of the trigger member 60, a lever 55 for the spring 70 placing therearound, and a handle 51 extending through the channel 344.

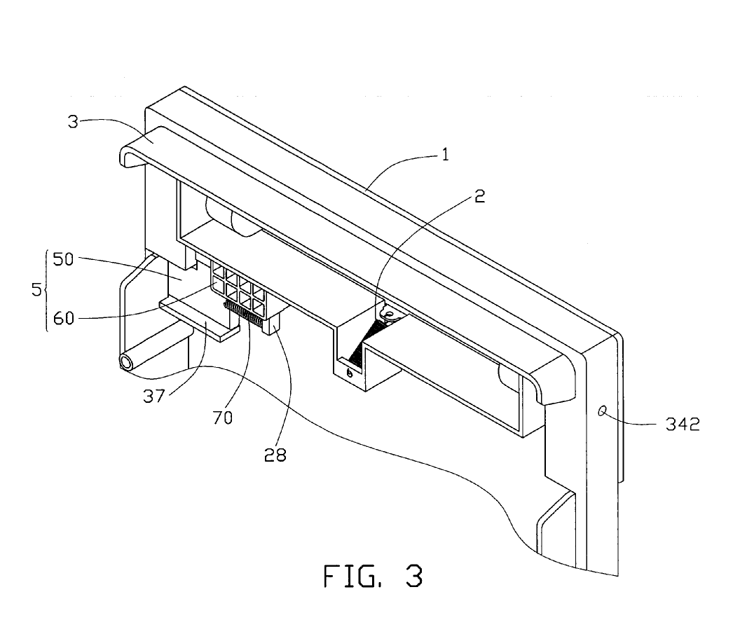

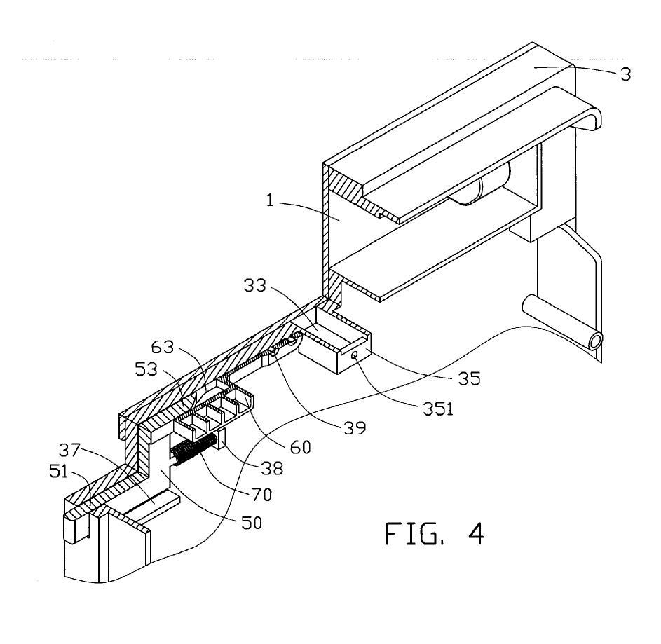

Referring also to FIG. 3 to FIG. 5, in assembly, the relay members 4 are assembled to the cover 1 and bezel 3. The relay members 4 are received in the slots 32 of the bezel 3, with the first shafts 45 pivotally engaging in the first holes 342. The second shafts 47 of the relay members 4 pivotally engage in the second holes 151 of the tabs 15 of the cover 1. Two ends of the resilient member 2 are separately fixed in the first fixing aperture 351 of the bezel 3 and the second fixing aperture 131 of the cover 1. The button assembly 5 is attached to the bezel 3. The trigger member 60 is attached to the bezel 3, with the fixing pins 39 extending through the through holes 651 thereof. The handle 51 of the button 50 extends through the channel 344 of the bezel 3. The button 50 slides along the guiding tab 37. The spring 70 is placed around the lever 55 of the button 50 and the post 381 of the block 38. The wedge portion 53 of the button 50 contacts the sloping portion 63 of the trigger member 60.

To open the cover 1, the handle 51 of the button 50 is pushed inwardly. The wedge portion 53 abuts against the sloping portion 63 of the trigger member 60 and the spring 70 is depressed. The touch portion 61 is moved to trigger a switch of the storage device. The storage device is moved out from the opening 31 of the bezel 3 and gradually urges the protrusions 11 to propel the cover 1 outwardly. The resilient member 2 is stretched. The relay members 4 pivot outwardly around the first shafts 45. At the same time, the cover 1 is rotated outwardly about the second shafts 47. Thus the cover 1 is gradually opened and the storage device can be operated. The spring 70 rebounds when the button 50 is released. The button assembly 5 accordingly moves back to its original position. The resilient member 2 rebounds and the cover 1 covers the bezel 3 again.

It is believed that the present embodiment and its advantages will be understood from the foregoing description, and it will be apparent that various changes may be made thereto without departing from the spirit and scope of the invention or sacrificing all of its material advantages, the example hereinbefore described merely being a preferred or exemplary embodiment.

What is claimed is:

1. A cover mechanism for protecting a storage devices installed in an electronic device, the cover mechanism comprising:
a bezel comprising an opening defined therein for the storage device passing therethrough, a pair of slots besides the opening, and a pair of first holes connecting to the slots;
a cover covering the opening of the bezel and comprising a pair of second holes defined therein;
a pair of relay members received in the slots, each of the relay members comprising a first shaft, and a second shaft arranged at two opposite ends thereof, the first shafts engaging in the first holes, the second shaft engaging in the second holes; and
a resilient member disposed between the cover and the bezel.

2. The cover mechanism as claimed in claim 1, wherein each of the relay members comprises a resilient tab, the first shafts extend from free ends of the resilient tabs.

3. The cover mechanism as claimed in claim 1, wherein the cover comprises a pair of tabs extending therefrom, the second holes are defined in the tabs.

4. The cover mechanism as claimed in claim 1, wherein the first holes are defined in sidewalls of the bezel and connect to the slots.

5. The cover mechanism as claimed in claim 1, wherein a recess is defined in the bezel and connects to a lower portion of the opening.

6. The cover mechanism as claimed in claim 5, wherein the bezel comprises a first fixing board defining a first fixing aperture, the cover comprises a second fixing board with a second fixing aperture, the resilient member is a coil spring and received in the recess, two ends of the coil spring are fixed in the first and second fixing apertures.

7. The cover mechanism as claimed in claim 1, wherein the cover comprises a pair of protrusions movably received in the opening of the bezel, the protrusions have triangular configurations.

8. The cover mechanism as claimed in claim 1, wherein the bezel further comprises a channel defined in a sidewall thereof, for a button assembly extending therethrough.

9. The cover mechanism as claimed in claim 8, wherein the button assembly comprises a button slidably attached to the bezel, and a trigger member with one end fixed on the bezel.

10. The cover mechanism as claimed in claim 9, wherein the button comprises a wedge portion, the trigger member comprises a sloping portion engagingly abutted against by the wedge portion.

11. A cover mechanism for protecting a storage devices installed in an electronic device, the cover mechanism comprising:
a bezel defining an opening therein;
a cover movably covering the opening of the bezel; and
at least one relay member attached to the bezel, said relay member pivotally engaging with the bezel and the cover at two ends thereof.

12. The cover mechanism as claimed in claim 11, further comprises a resilient member disposed between the cover and the bezel.

13. The cover mechanism as claimed in claim 12, wherein the bezel comprises a first fixing board defining a first fixing aperture, the cover comprises a second fixing board with a second fixing aperture, the resilient member is a coil spring, two ends of the coil spring are fixed in the first and second fixing apertures.

14. The cover mechanism as claimed in claim 11, wherein said relay member comprises a first shaft, and a second shaft disposed at two ends thereof.

15. The cover mechanism as claimed in claim 14, wherein said relay member comprises a resilient tab, the first shaft forms from a free end of the resilient tab.

16. The cover mechanism as claimed in claim 14, wherein the bezel defines at least one slot besides the opening for receiving said relay member therein, a first hole is defined in a corresponding sidewall of the bezel to pivotally receive the first shaft therein.

17. The cover mechanism as claimed in claim 16, wherein the cover comprises a tab extending therefrom, the tab defines a second hole therein, the second shaft is pivotally received in the second hole.

18. The cover mechanism as claimed in claim 11, wherein the cover comprises a pair of protrusions movably received in the opening of the bezel, the protrusions have triangular configurations.

19. The cover mechanism as claimed in claim 11, wherein the bezel further comprises a channel defined in a sidewall thereof, for a button assembly extending therethrough.
